(19) United States
(12) Patent Application Publication
(10) Pub. No.: US 2009/0090980 A1
(43) Pub. Date: Apr. 9, 2009

(54) ASYMMETRIC-LDD MOS DEVICE

(76) Inventors: Mingchu King, Taichung City (TW); Albert Chin, LuChu Township (TW)

Correspondence Address: ANTHONY R. BARKUME, 20 GATEWAY LANE, MANORVILLE, NY, 11949, US

(21) Appl. No.: 11/868,546

(22) Filed: Oct. 8, 2007

(51) Int. Cl. H01L 29/78; H01L 29/76; H01L 29/94; H01L 31/00

(52) U.S. Cl. 257/408; 257/344; 257/E29.268

(57) ABSTRACT

The present invention proposes a new asymmetric-lightly-doped drain (LDD) metal oxide semiconductor (MOS) transistor that is fully embedded in a CMOS logic. The radio frequency (RF) power performance of both conventional and asymmetric MOS transistor is measured and compared. The output power can be improved by 38% at peak power-added efficiency (PAE). The PAE is also improved by 16% at 10-dBm output power and 2.4 GHz. These significant improvements of RF power performance by this new MOS transistor make the RF-CMOS system-on-chip design a step further. Index Terms—Lightly-doped-drain (LDD), metal oxide semiconductor field effect transistor (MOSFET), metal oxide semiconductor (MOS) transistor, radio frequency (RF) power transistor.

### FIELD OF THE INVENTION

The present invention is related to an MOS device, particularly to an asymmetric-LDD MOS transistor device.

### BACKGROUND OF THE INVENTION

### I. Introduction

The rapid technology evolution of Si metal oxide semiconductor field effect transistor (MOSFET) is beneficial for integrated circuit (IC) design with higher device speed and cost reduction. Besides the advantages on digital performance, the scaling of CMOS technology also has largely improved the radio frequency (RF) performance of MOS devices. The most significant improvement along with CMOS technology scaling is the larger RF gain, higher cut-off frequency, and maximum oscillation frequency. This has made CMOS device technology the prime choice for RF system-on chip (SoC) application such as WCDMA, W-LAN, and ultra wide band (UWB) wireless communication. However, the low drain breakdown voltage of CMOS transistors restricts the use of CMOS for power amplifiers. This limitation for high voltage operation significantly reduces the maximum output power and efficiency for CMOS devices. Therefore, the RF SoC design, which includes the RF power amplifier, is a long time historical challenge for using the baseline CMOS logic process. In the past, LDMOS transistors were introduced to overcome the low drain break-down voltage issue at the expense of complex process and lower operation speed. However, this is opposite to the technology trend for wireless communication, where continuously increasing operation frequency is needed.

### SUMMARY OF THE INVENTION

An objective of the present invention is to overcome the low breakdown voltage issue and improve the RF power performance.

Another objective of the present invention is to provide an asymmetric-lightly-doped-drain (LDD) MOS transistor for high frequency RF power application.

Another objective of the present invention is to provide an asymmetric-LDD MOS transistor fully embedded in the conventional foundry logic process.

### BRIEF DESCRIPTION OF THE INVENTION

According to the present invention, an asymmetric-LDD MOS device comprises:

a silicon substrate of a first conductivity type being selectively covered with a gate insulating film on a main surface thereof; a gate electrode having a first spacer and a second spacer, and at least at first portions in vicinity of bottom surfaces adjacent to the gate insulating film;

a first diffusion region having a low concentration of a second conductivity type opposite to the first conductivity type, the first diffusion region being provided in the silicon substrate to be coplanar with the main surface, and an edge of the first diffusion region being aligned with an edge of the first spacer;

a pair of second diffusion regions having a high concentration of the second conductivity type, the second diffusion regions being provided in the silicon substrate to be coplanar with the main surface, and two edges of the second diffusion regions being aligned with edges of the first spacer and the second spacer respectively, the first spacer being adjacent to the first diffusion region, the second spacer being adjacent to the silicon substrate, thereby providing a pair source.drain regions.

In accordance with one aspect of the present invention, a pocket implant region of the first conductivity type have two sides and is provided in the silicon substrate. A first one of the two sides is adjacent to the first one of the second diffusion regions and a second one of the two sides is adjacent to the first diffusion region.

In accordance with one aspect of the present invention, a third diffusion region has a low concentration of a first conductivity type. The third diffusion region is provided in the silicon substrate to be coplanar with the main surface. And an edge of the third diffusion region is aligned with an edge of the second spacer.

In accordance with one aspect of the present invention, the first conductivity type is P type, and the second conductivity type is N type.

In accordance with one aspect of the present invention, the first one of the second diffusion regions forms a source electrode, and the second one of the second diffusion regions forms a drain electrode.

The present invention may best be understood through the following description with reference to the accompanying drawings, in which:

### BRIEF DESCRIPTION OF THE DRAWINGS

FIG. 1 shows a sectional view of an asymmetric-LDD MOS device according to the present invention;

FIG. 2 shows a sectional view of an asymmetric-LDD MOS device with P-type pocket implant region according to the present invention;

FIG. 3 shows a sectional view of an asymmetric-LDD MOS device with P-LDD region according to the present invention;

FIG. 4 shows a drawn layer added to conventional MOS transistor to realize the asymmetric-LDD MOS transistor;

FIG. 5 shows the comparison of drain breakdown voltage (BVdss) at Vgs=0 V; the devices have a physical gate length of 0.23 μm. Significantly larger BVdss is obtained using the new design;

FIG. 6 shows the measured RF output power and PAE versus the input power for conventional and asymmetric-LDD MOS transistors at 2.4 GHz; the matching point is adjusted for the maximum power output point in the load pull system; higher output power and broader PAE are measured for this new asymmetric-LDD MOS transistor; and

FIG. 7 shows the carrier to third-order inter-modulation product output power ratio (C/IM3) versus the output power for the two different devices measured at 2.4 GHz.

### DETAILED DESCRIPTION OF THE PREFERRED EMBODIMENTS

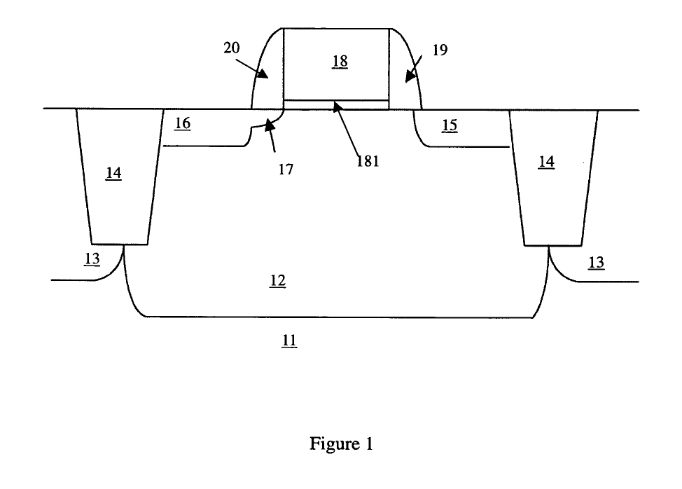

FIG. 1 shows a sectional view of an asymmetric-LDD MOS device according to the present invention. There are a P-substacte 11, a Pwell 12, a Nwell 13, a STI 14, a N+ drain electrode 15, a N+ source electrode 16, a N− LDD region 17, a gate electrode 18, a first spacer 20, and a second spacer 19 in FIG. 1. The P-substacte 11 and the Pwell 12 form a silicon substrate. The gate electrode 18 includes a gate insulating film adjacent to the Pwell 12. The first spacer 20 is adjacent to the N− LDD region 17, but the second spacer 19 is adjacent to the Pwell 12, which is the major difference to conventional MOS transistor. In other words, the major difference to the prior MOS transistor is no N− LDD region at drain side. Therefore, the formed depletion region under reverse drain bias can sustain large voltage for RF Power application.

According the present invention, the MOS device structure with spacer at both source and drain sides but only LDD implant at the source side. For a NMOS in Pwell with N+ S/D implant, there is no N− LDD implant at the drain side. Similarly, for a PMOS in NWell with P+S/D implant, there is no P-LDD implant at the drain side.

The device structures described in FIG. 1 have spacer but no LDD implant of the same polarity at the drain side. This device structure creates a potential barrier at the drain side. While apply drain voltage, a depletion layer will be created and extended into the region beneath the spacer. The applied voltage will drop across the depletion region beneath the spacer. The actual voltage at the edge of gate is reduced due to voltage drop across the depletion region. Therefore, the drain breakdown voltage is increased.

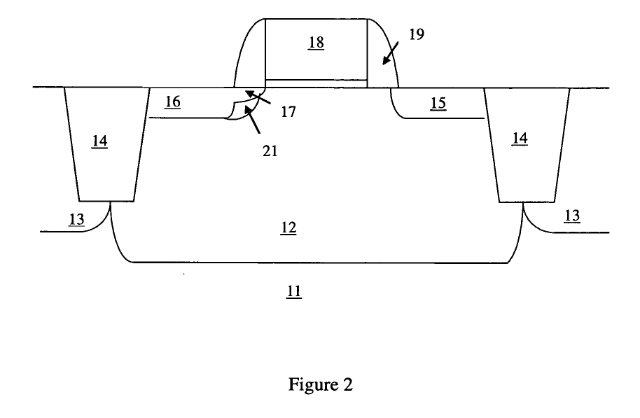

FIG. 2 shows a sectional view of an asymmetric-LDD MOS device with P-type pocket implant region according to the present invention. Comparing to FIG. 1, there is a P-type pocket implant region 21 among the N+ source electrode 16, the N− LDD region 17, and Pwell 12.

A modification is made to add one implant step with P-type pocket implant region 21 by the same N-LDD mask layer at the source side for a NMOS in P-Well with N+S/D implant. Similarly, the added implant layer is N-type pocket implant at the source side for a PMOS in N-Well with P+S/D implant.

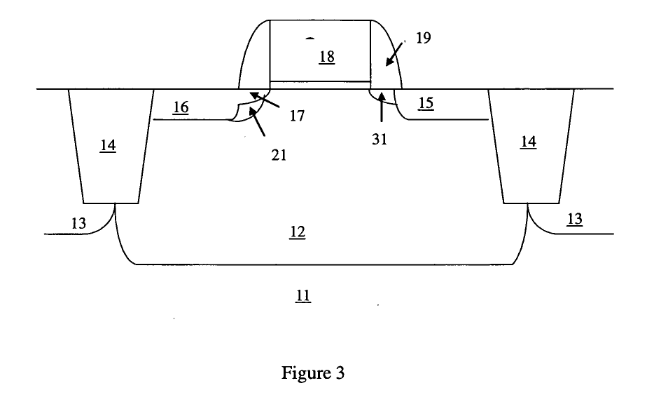

FIG. 3 shows a sectional view of an asymmetric-LDD MOS device with P− LDD region according to the present invention. Comparing to FIG. 2, there is a P− LDD region 31 among the Pwell 12, the N+ drain electrode 15 and the second spacer 19.

The added reverse-type LDD (i.e. P− LDD region 31) at the drain side will create a depletion region less sensitive to drain voltage and increase the drain breakdown voltage further compared to the device in FIG. 1.

Method to Realize the Asymmetric-LDD MOS in Semiconductor Process:

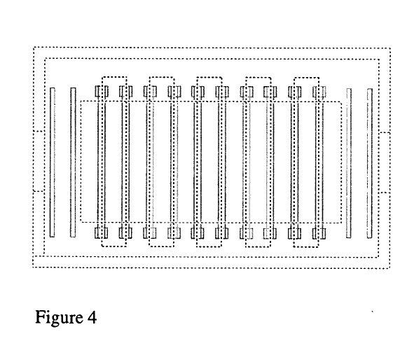

FIG. 4 shows a drawn layer added to conventional MOS transistor to realized the asymmetric-LDD MOS transistor.

The structures of this asymmetric-LDD MOS transistor are shown schematically in device structure FIG. 1 and FIG. 2. To increase the transistor breakdown voltage for RF power application, the LDD region at the drain side was removed but keeping the spacer, which is the major difference to a conventional MOS transistor. This was accomplished by blocking the ion implantations to LDD region and Halo process at the drain side for the new transistor.

The additional steps to prepare the database of this asymmetric-LDD MOS transistors are listed as below:

1. Draw a layer with one edge at the middle of gate node of a MOS transistor and the other edge to cover the whole drain region. For a finger-type layout with shared drain for adjacent MOS transistors, the drawn layer will have edges at the middle of the gate nodes of the two adjacent MOS transistors as illustrated in FIG. 4.

2. Boolean operation for LDD masks will remove the drawn region.

3. For the P-LDD region 31 in FIG. 3, an extra mask can be generated by using the extra drawn layer for a reverse-type LDD implant.

### II. Experimental Procedure

The structure of the new asymmetric-LDD MOS transistor is shown schematically in FIG. 1. To increase the transistor breakdown voltage for RF power application, the LDD region at the drain side was removed, which is the major difference to a conventional MOS transistor. This was accomplished by blocking the ion implantations to LDD region and Halo process at the drain side for the new transistor. The devices we studied in this work are multiple fingers MOS transistors with 10 gate fingers, 0.23-μm gate length and 5 μm width. For comparison, the same interconnect and RF layout were used. The devices were fabricated by a standard logic process provided by IC foundry. The RF power characterization was carried out by on-wafer measurements at 2.4 GHz using an ATN load-pull system, where the input and output impedance matching conditions were selected to optimize the output power.

### III. Results and Discussion

A. Drain Breakdown Voltage

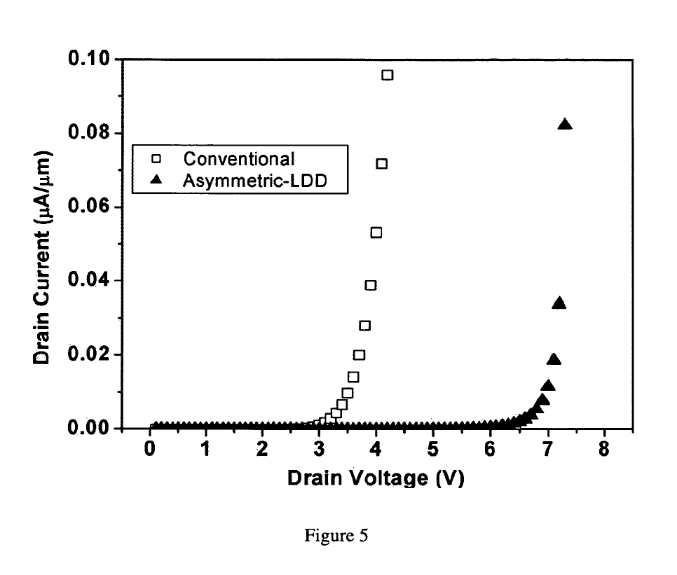

FIG. 5 shows the comparison of dc drain breakdown voltage for conventional and asymmetric-LDD MOS transistors. For the conventional MOS transistor, a BVdss of 3.6 V was measured at Ids of 0.1 μA/μm and Vgs of 0 V. However, the maximum drain bias is only 1.8 V if considering the reliability of 10 years continuous operation. In sharp contrast, the BVdss of the asymmetric-LDD transistor is increased to 7.0 V as measured under the same criteria. This large improvement of BVdss is due to the designed wide depletion region beneath the spacer region and between the drain and substrate. In contrast, the existing n+-LDD LDD in a conventional CMOS transistor just provides an electrically short path between inversion channel and drain. Such wide depletion region in the new design can support significantly larger reverse-biased drain voltage than conventional case. This new device design with large drain depletion region is similar to bipolar transistor from the device physics point-of-view. Since the electrons can pass through the drain depletion region with fast saturation velocity under large reverse biased voltage, little degradation of operation speed can be expected. Therefore, this new asymmetric-LDD MOS transistor can effectively resolve the fundamental challenge of low breakdown voltage issue in the small energy bandgap Si MOS transistor. In the meanwhile this device still preserves the high frequency operation of sub-μm MOS transistors with cutoff frequency (ft) of 34 GHz close to the 35 GHz of conventional MOS. This device also gives a higher maximum oscillation frequency (fmax) of 86 GHz than the 76 GHz of conventional MOS. It is generally known the increasing breakdown voltage may lower down the drive current. However, the new asymmetric MOSFET can be operated at a higher voltage that gives close drive current (10.44 mA at Vds=2.5 V) to conventional device (9.76 mA at Vds=1.8 V). One major reliability issue for conventional deep sub-μm MOSFET is the hot carrier injection (HCI) degradation, caused by impact ionization and electrons injection into the gate oxide by high drain field. From detailed transistor simulation T-Supreme Medici Analysis (TMA), the asymmetric-LDD device design pushes the peak electric field away from the gate edge and reduces the electron injection into the gate oxide. Thus, good HCI reliability may be expected for this new device.

B. RF Power Performance

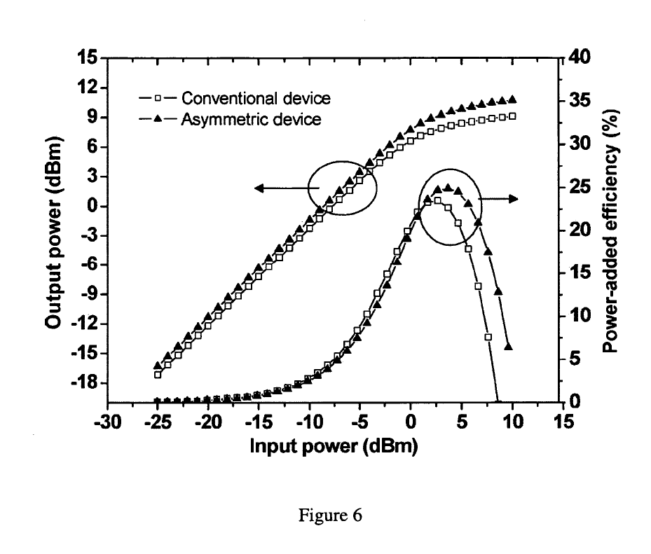

We have further measured the RF power performance in the asymmetric-LDD MOS transistor. The output power and PAE versus the input power of both the conventional and asymmetric-LDD MOS transistors are shown on FIG. 6. The dc bias point of the conventional MOS transistor is at Vgs of 1.2 V and Vds of 1.8 V under the maximum trans-conductance condition. For the asymmetric-LDD MOS transistor, the dc bias point is at Vgs of 1.2 V and an increased Vds of 2.5 V. Here only 2.5 V is chosen in this study although higher bias voltage can be used after detailed reliability study. The output power is increased by 38% from 130 to 180 mW/mm, as measured at 2.4 GHz under peak PAE condition. The PAE of asymmetric device at low input power is slightly lower than conventional device, which may be due to inferior electron transportation through the potential barrier at drain side. But this effect becomes less affective due to the electron tunneling via potential barrier at high electric field and bias voltage. In addition, broader maximum PAE region is also obtained in the asymmetric-LDD MOS transistor that provides wider design margin, in combination with the slightly increasing peak PAE from 23.5% to 24.9%. Moreover, when both devices are biased for 10 dBm output power measured at 2.4 GHz, the PAE can be improved by 16%. These achieved large improvements of power performance are a new breakthrough in RF Si CMOS transistors and important for wireless communication IC and SoC.

C. Linearity in Saturation

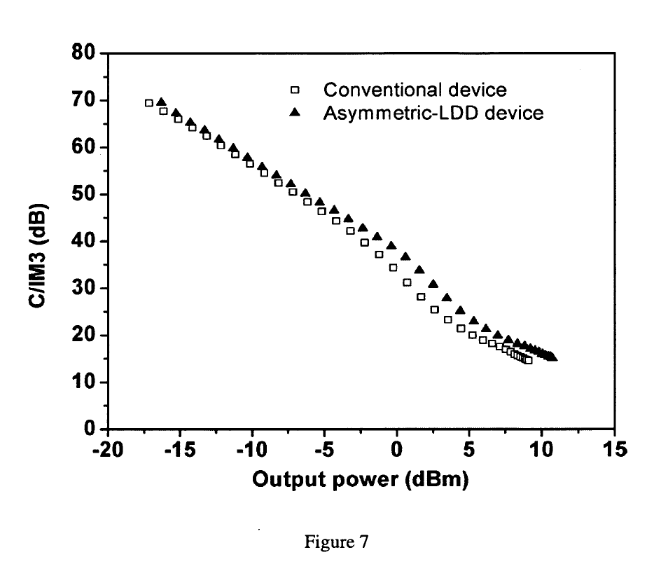

The carrier to third-order inter-modulation product output power (C/IM3) ratio is another important factor for RF power application. We have compared the C/IM3 for the two MOS transistors and the results are shown in FIG. 7. The asymmetric-LDD MOS transistor still shows a slightly improved C/IM3 ratio of 0.7 dB at peak PAE. The improvement is due to the reduced gate-drain coupling capacitance (Cgd) by removing the LDD implant under the spacer; this reduces the interference between gate and drain nodes and therefore improves the linearity. Therefore, significantly better output power density is achieved by the asymmetric-LDD MOS transistor with even slightly better linearity and PAE. However, the drain resistance (Rgd) is also increased along with reduced Cgd, which causes an increased threshold voltage.

### IV. Conclusion

The low drain breakdown voltage of a conventional CMOS transistor is the major restriction of RF power performance. We have designed an asymmetric-LDD MOS transistor to increase the drain breakdown voltage from 3.6 to 7.0 V. By raising the drain operation voltage beyond conventional CMOS device, the RF output power of this new transistor is improved by as much as 38% at peak PAE, with the added merit of broader peak PAE region and useful for wider design margin. By removing LDD at the drain side but keeping the spacer, an N+-P− depletion region is formed at the drain side. The thickness of this capacitive depletion region is significantly larger than conventional symmetrical design, which allows larger voltage applied to drain. Thus, this drain engineering can improve the drain breakdown voltage and power performance. This new asymmetric-LDD MOS transistor is fully embedded in the standard CMOS logic process provided by foundries without any process modification.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An asymmetric-LDD MOS device comprising:
a silicon substrate of a first conductivity type being selectively covered with a gate insulating film on a main surface thereof;
a gate electrode having a first spacer and a second spacer, and at least at first portions in vicinity of bottom surfaces adjacent to said gate insulating film;
a first diffusion region having a low concentration of a second conductivity type opposite to said first conductivity type, said first diffusion region being provided in said silicon substrate to be coplanar with said main surface, and an edge of said first diffusion region being aligned with an edge of said first spacer; and
a pair of second diffusion regions having a high concentration of said second conductivity type, said second diffusion regions being provided in said silicon substrate to be coplanar with said main surface, and two edges of said second diffusion regions being aligned with edges of said first spacer and said second spacer respectively, said first spacer being adjacent to said first diffusion region, said second spacer being adjacent to said silicon substrate, thereby providing a pair source drain regions.

2. An asymmetric-LDD MOS device according to claim 1, further comprising:
a pocket implant region of said first conductivity type having two sides and being provided in said silicon substrate; a first one of said two sides being adjacent to said first one of said second diffusion regions, and a second one of said two sides being adjacent to said first diffusion region.

3. An asymmetric-LDD MOS device according to claim 2, further comprising:
a third diffusion region having a low concentration of a first conductivity type, said third diffusion region being provided in said silicon substrate to be coplanar with said main surface, and an edge of said third diffusion region being aligned with an edge of said second spacer.

4. An asymmetric-LDD MOS device according to claim 1, wherein:
said first conductivity type is P type; and
said second conductivity type is N type.

5. An asymmetric-LDD MOS device according to claim 1, wherein:
said first one of said second diffusion regions forms a source electrode; and
said second one of said second diffusion regions forms a drain electrode.
